(19) United States
(12) Patent Application Publication
(10) Pub. No.: US 2014/0167276 A1
(43) Pub. Date: Jun. 19, 2014

(54) SUBSTRATE FOR SEMICONDUCTOR PACKAGE, SEMICONDUCTOR PACKAGE USING THE SUBSTRATE, AND METHOD OF MANUFACTURING THE SEMICONDUCTOR PACKAGE

(71) Applicant: SK HYNIX INC., Icheon-si Gyeonggi-do (KR)

(72) Inventor: Seung Jee KIM, Seongnam-si Gyeonggi-do (KR)

(73) Assignee: SK HYNIX INC., Icheon-si Gyeonggi-do (KR)

(21) Appl. No.: 13/846,829

(22) Filed: Mar. 18, 2013

(30) Foreign Application Priority Data
Dec. 18, 2012 (KR) 10-2012-0148895

(51) Int. Cl. H01L 23/48; H01L 21/50

(52) U.S. Cl. CPC H01L 23/48; H01L 21/50
USPC 257/773; 438/106

(57) ABSTRACT

A semiconductor package includes a package substrate, semiconductor chips adhered over the package substrate and configured to include bonding pads, one or more dummy patterns disposed at specific intervals in peripheries of the semiconductor chips, an insulating layer formed over the package substrate including the semiconductor chips and the dummy patterns so that the bonding pads are exposed, and wire patterns formed over the insulating layer and coupled with the bonding pads.

### CROSS-REFERENCE TO RELATED APPLICATION

The present application claims priority under 35 U.S.C 119(a) to Korean Application No. 10-2012-0148895, filed on Dec. 18, 2012, in the Korean Intellectual Property Office, which is incorporated herein by reference in its entirety set forth in full.

### BACKGROUND

1. Technical Field

Various embodiments of the present invention generally relate to a semiconductor package, and more particularly, to a substrate for a semiconductor package, a semiconductor package using the substrate, and a method of manufacturing the semiconductor package.

2. Related Art

An electronic element for an electronic device can include a variety of active and passive circuit elements. The electronic circuit elements can be integrated into a semiconductor chip or a semiconductor substrate also called a die. The electronic elements of an integrated circuit can be mounted on the Printed Circuit Board PCB of an electronic device, such as a computer, a mobile device, or a data storage, in the form of a package mounted on a package substrate including circuit wires, such as a PCB or a silicon (Si) interposer. Additionally, in the packaging technology for semiconductor devices, since a greater number of inputs and outputs and high performance are required as the degree of integration of semiconductor devices is increased, researches are carried out in order to reduce the total size of packages so that an assembly process of mounting a semiconductor chip on a substrate can be performed rapidly and precisely and a greater number of packages can be disposed in a limited storage space.

In methods of disposing semiconductor packages in a limited space and mounting a greater number of packages on a substrate, the development of an embedded package in which a semiconductor chip is disposed within a substrate not on a surface of the substrate is in progress. In a process of manufacturing the embedded package, an insulating layer is used in order to protect the semiconductor chip and separate the semiconductor chip from an adjacent semiconductor chip. If the insulating layer is formed in the state in which the semiconductor chips are spaced apart from one another at specific intervals, however, the height of the insulating layer in a space part between the semiconductor chips is lowered, thereby generating a deviation in the thickness of the insulating layer in each region. This deviation in the thickness of the insulating layer results in regions that are not partially plated and failures, such as a chip crack or the lifting of a die.

### SUMMARY

In an embodiment, a substrate for a semiconductor package, includes: a substrate panel; semiconductor chips adhered over the substrate panel; at least one dummy pattern disposed at intervals in peripheries of the semiconductor chips; and an insulating layer formed over the substrate panel including the semiconductor chips and the dummy pattern.

In an embodiment, a semiconductor package includes a package substrate, semiconductor chips adhered over the package substrate and configured to include bonding pads, one or more dummy patterns disposed at specific intervals in the peripheries of the semiconductor chips, an insulating layer formed over the package substrate including the semiconductor chips and the dummy patterns so that the bonding pads are exposed, and wire patterns formed over the insulating layer and coupled with the bonding pads.

The dummy patterns are consecutively jointed together in a line form along the outer edges of the semiconductor chips.

The dummy patterns include patterns configured to have one or more pillars and consecutively disposed along the outer edges of the semiconductor chips.

The dummy patterns are configured to have the same height as the semiconductor chips.

The dummy patterns are made of an insulating material including solder resist or epoxy resins.

The insulating layer includes thermosetting resins or thermoplastic resins.

In an embodiment, In an embodiment, a method of manufacturing a semiconductor package including: forming semiconductor chips over a substrate; disposing a dummy pattern in peripheries of the semiconductor chips over the substrate; forming an insulating material over the substrate including the semiconductor chips and the dummy pattern; and using the dummy pattern to control a drift velocity of the insulating material.

In an embodiment, a method of manufacturing a semiconductor package includes forming semiconductor chips configured to include bonding pads over the entire surface of a package substrate, disposing one or more dummy patterns made of a conductive material, disposed over the package substrate, and arranged at specific intervals in the peripheries of the semiconductor chips, forming an insulating layer over the package substrate including the semiconductor chips and the dummy patterns and configured to have the bonding pads exposed through the insulating layer, first wire patterns formed over the insulating layer and coupled with the bonding pads and the dummy patterns made of the conductive material, through electrodes configured to penetrate from the rear of the package substrate and coupled with the dummy patterns, and forming second wire patterns in the through electrodes and on the rear of the package substrate

### BRIEF DESCRIPTION OF THE DRAWINGS

The above and other aspects, features and other advantages will be more clearly understood from the following detailed description taken in conjunction with the accompanying drawings, in which:

FIG. 1 is a diagram illustrating a substrate for a semiconductor package in accordance with an embodiment of the present invention;

FIGS. 2 and 3 are diagrams illustrating a substrate for a semiconductor package in accordance with an embodiment of the present invention;

FIG. 4 is a diagram illustrating a semiconductor package in accordance with an embodiment of the present invention;

FIGS. 5 to 13 are diagrams illustrating a method of manufacturing a semiconductor package in accordance with an embodiment of the present invention; and

FIGS. 14 to 22 are diagrams illustrating a method of manufacturing a semiconductor package in accordance with an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

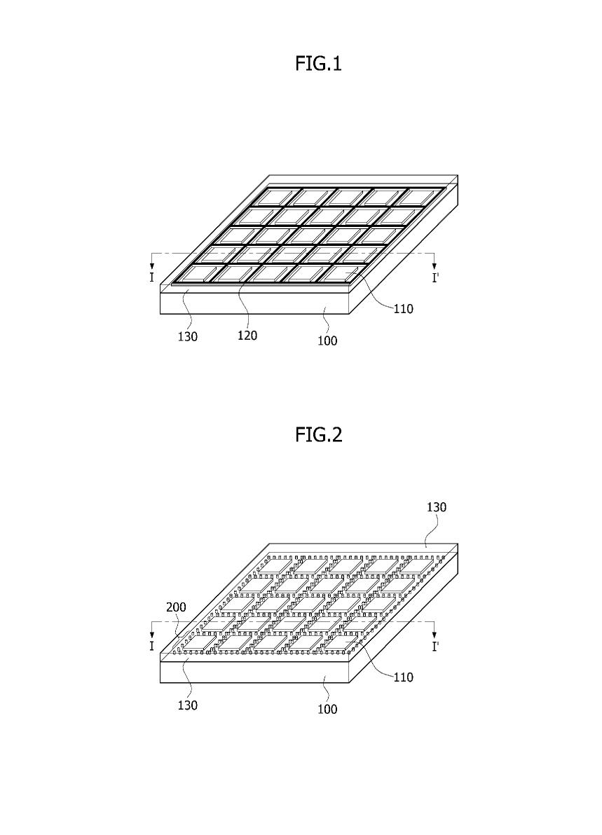

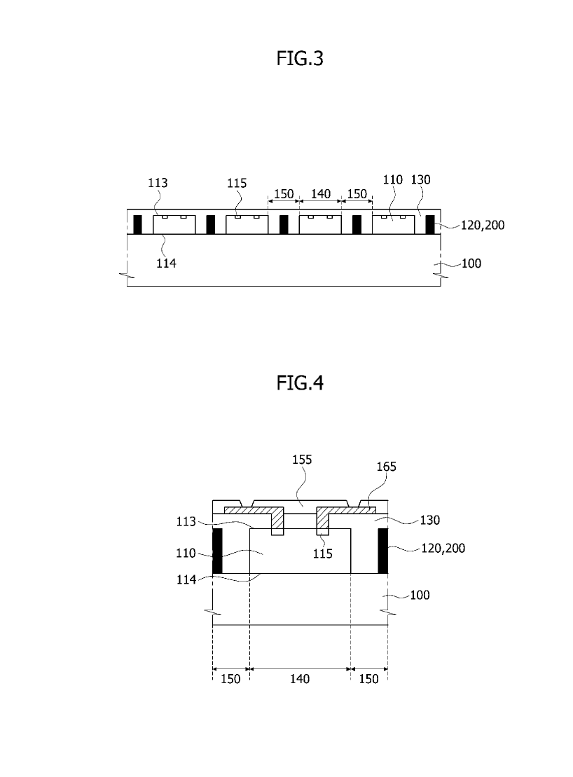

FIG. 1 is a perspective view illustrating a substrate for a semiconductor package in accordance with an embodiment of the present invention. FIG. 2 is a perspective view illustrating a substrate for a semiconductor package in accordance with an embodiment of the present invention. Furthermore, FIG. 3 is a cross-sectional view of the substrate taken along line I-I′ of FIG. 1 or 2.

Referring to FIGS. 1, 2, and 3, the substrate for a semiconductor package in accordance with embodiments of the present invention may include a substrate panel 100 and a plurality of semiconductor chips 110 formed over the substrate panel 100. The semiconductor chips 110 may be formed over the substrate panel 100 with an adhesion layer (not shown) interposed between the semiconductor chips 110 and the substrate panel 100. Bonding pads 115 can be disposed along the center line of the semiconductor chip 110, but not limited thereto.

One or more dummy patterns 120, 200 may be formed on the substrate panel 100 and may be disposed at specific intervals in the peripheries of the plurality of semiconductor chips 110. Referring to FIG. 3, the dummy patterns 120, 200 may be disposed in peripheral regions 150 that surround a main region 140 in which the semiconductor chip 110 may be disposed. The peripheral region 150 may include a space disposed between adjacent semiconductor chips 110. Referring to FIG. 1, the dummy patterns 120 in accordance with an embodiment of the present invention can be consecutively jointed together in a line formed along the outer edges of the semiconductor chips 110 and can be formed in a mesh form, for example.

The dummy patterns 200 in accordance with an embodiment of the present invention, as shown in FIG. 2, may include dummy patterns 200 configured to include one or more pillars and consecutively disposed along the outer edges of the semiconductor chips 110. In this case, the dummy patterns 120, 200 can be configured to have the same height or substantially the same height as the semiconductor chips 110. Furthermore, the dummy patterns 120, 200 may be made of insulating materials and can be made of solder resist materials or epoxy resins, for example.

Structures disposed over the package substrate, for example, the semiconductor chips 110 and the dummy patterns 120, 200 may be embedded by an insulating layer 130. The insulating layer 130 may include thermoplastic resins or thermosetting resins. The dummy patterns 120, 200 may be disposed between the semiconductor chips 110 and may be disposed in the peripheral regions 150 (see FIG. 3) through which the substrate panel 100 is not exposed because the semiconductor chips 110 are not disposed in the peripheral regions 150. Accordingly, the dummy patterns 120, 200 may be disposed in portions in which the semiconductor chips 110 are not disposed and between portions in which the semiconductor chips 110 are present, thus functioning to prevent the occurrence of a difference in the thickness of the insulating layer 130. In other words, the dummy patterns 120, 200 enable the insulating layer 130 to have a uniform thickness in the entire substrate panel 100.

Since the insulating layer 130 may be configured to have a uniform thickness in the entire substrate panel 100 by way of the dummy patterns 120, 200 disposed between the semiconductor chips 110 as described above, a failure, such as a region not partially plated due to an irregular thickness, a crack occurring in a semiconductor chip, or a failure, such as the lifting of a semiconductor chip, can be prevented.

FIG. 4 is a cross-sectional view illustrating a semiconductor package in which one semiconductor chip 110, for example, may be disposed over the substrate panel 100 of FIG. 3 and on which a wiring process has been performed.

Referring to FIG. 4, the semiconductor package in accordance with an aspect of the present invention has a structure in which a semiconductor chip 110 may be disposed over a substrate panel 100. Each of the semiconductor chips 110 disposed over the substrate panel 100 may include a first face 113 configured to have bonding pads 115 formed therein and a second face 114 configured to face the first face 113. The substrate panel 100 can be adhered to the second face 114 of the semiconductor chip 110 through the medium of an adhesion layer (not shown). One or more dummy patterns 120 or 200 may be disposed at specific intervals in peripheral regions 150 disposed in the peripheries of a main region 140 in which the semiconductor chip 110 may be disposed. Here, the dummy patterns 120 or 200 can be consecutively jointed together in a line form along the outer edges of the semiconductor chips 110 and can be formed in a box form, for example. In some embodiments, as shown in FIG. 2, the dummy patterns 120 or 200 may include dummy patterns 200 configured to include one or more pillars and consecutively disposed along the outer edges of the semiconductor chip 110. An insulating layer 130 through which the bonding pads 115 are exposed is formed on the substrate panel 100 including the semiconductor chip 110 and the dummy patterns 120 or 200. Wire patterns 165 may be formed on the insulating layer 130 and are coupled with the bonding pads 115. An insulating mask 155 is formed on the wire patterns 165. The insulating mask 155 may include an insulating material through which parts of the wire patterns 165 to which external connection terminals will be connected are exposed. Although not shown, external connection terminals, for example, solder balls coupled with the wire patterns 165 exposed on the insulating mask 155 can be further formed.

A method of manufacturing a semiconductor package in accordance with an embodiment of the present invention is described below with reference to FIGS. 5 to 13.

FIGS. 5 to 13 are diagrams illustrating the method of manufacturing a semiconductor package in accordance with an embodiment of the present invention.

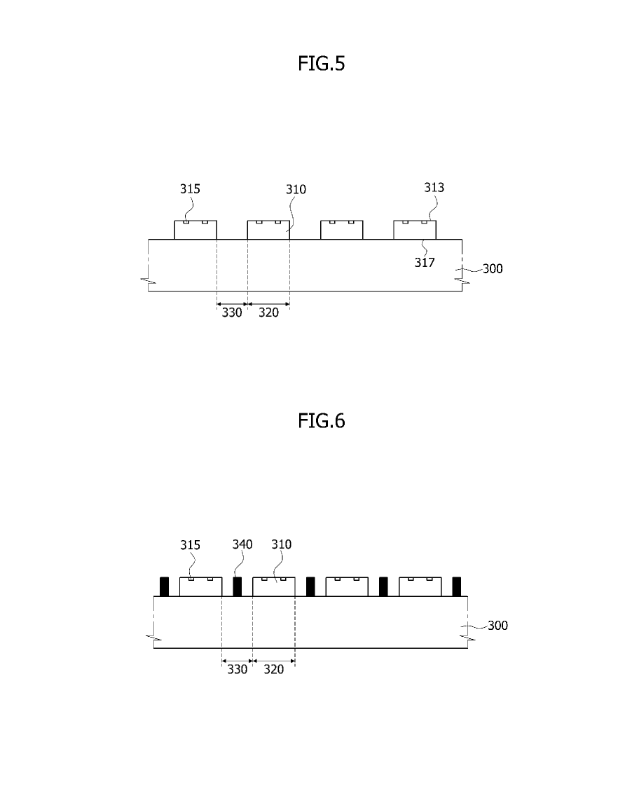

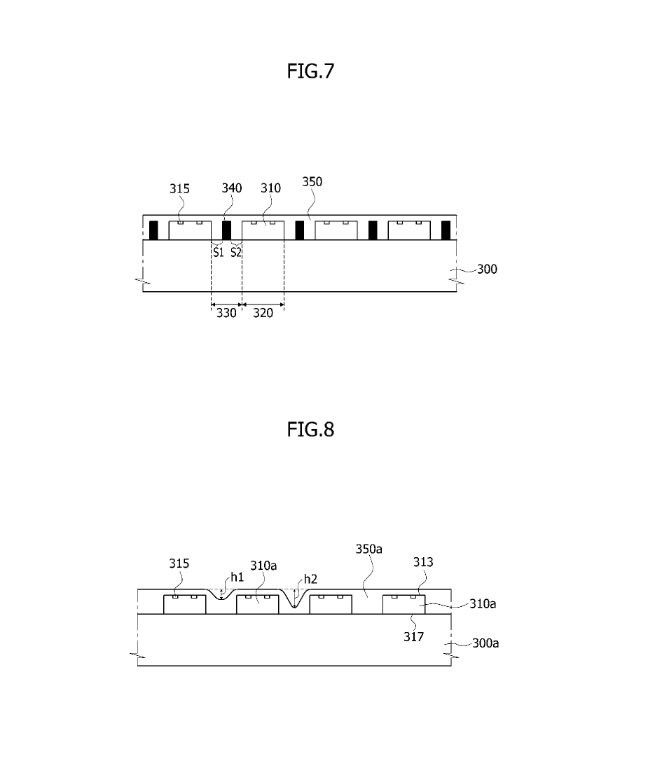

Referring to FIG. 5, a plurality of semiconductor chips 310 may be disposed over a substrate panel 300. Each of the semiconductor chips 310 may include a first face 313 configured to have bonding pads 315 formed therein and a second face 317 configured to face the first face 313. The bonding pads 315 (see also FIGS. 6 and 7) can be disposed along the central part of the semiconductor chip 310, but not limited thereto. The bonding pads 315 may include copper (Cu). The semiconductor chips 310 can be adhered to the substrate panel 300 through the medium of an adhesion layer (not shown). The semiconductor chip 310 may be disposed in the main region 320 of the substrate panel 300. A peripheral region 330 through which a surface of the substrate panel 300 is exposed may be disposed between adjacent semiconductor chips 310.

Referring to FIG. 6, one or more dummy patterns 340 may be disposed on the peripheral regions 330 of the substrate panel 300. The dummy patterns 340 may be disposed at specific intervals in the peripheries of the semiconductor chips 310 and may be disposed in the peripheral regions 330 that surround the main region 320 in which the semiconductor chip 310 may be disposed. The dummy patterns 340 can be formed by a photolithography process. Here, the dummy patterns 340 can be consecutively jointed together in a line form along the outer edges of the semiconductor chips 310 and can be formed in a mesh form (see FIG. 1), for example. In various embodiments, the dummy patterns 340 may include patterns configured to include one or more pillars and consecutively disposed along the outer edges of the semiconductor chips 310, as shown in FIG. 2. In this case, the dummy patterns 340 may be configured to have the same height or substantially the same height as the semiconductor chips 310. Furthermore, the dummy patterns 340 are made of an insulating material and can be made of solder resist or epoxy resins, for example.

Referring to FIG. 7, structures disposed over the substrate panel 300, for example, the semiconductor chips 310 and the dummy patterns 340 are filled with a first insulating layer 350. The first insulating layer 350 functions to protect the semiconductor chips 310. The first insulating layer 350 can be formed by a vacuum lamination method. To this end, a state of the insulating material of the first insulating layer 350 is changed into a flowable state by applying high pressure and high temperature higher than a melting point of the insulating material. The insulating material having the flowable state is coated on the entire surface so that the semiconductor chips 310 and space s1 and s2 between adjacent semiconductor chips 310 are buried. The insulating material is coated to a thickness enough to cover the entire surface of the semiconductor chips 310. In this case, the drift velocity of the insulating material is controlled by the dummy patterns 340 disposed in the spaces between the semiconductor chips 310, with the result that the insulating material has a uniform thickness in the entire substrate panel 300.

In contrast, as shown in FIG. 8, if an insulating layer 350a comprising of, for example, an insulating material is coated in the state in which dummy patterns are not disposed, a substrate panel 300a may include portions in which the insulating material is locally stacked thickly or thinly. Furthermore, regions in which semiconductor chips 310a may be disposed and regions through which a surface of the substrate panel 300a is exposed have different heights. In the state in which the semiconductor chips 310a and the substrate panel 300a are formed, an insulating material having flowability is coated and a curing process of forming the flowable insulating material into the insulating layer 350a by curing the flowable insulating material in a subsequent process is then performed. In this case, the portions in which the semiconductor chips 310a may be disposed and the portions through which the surface of the substrate panel 300a is exposed have a difference in height h1 and height h2 in the thickness of the insulating material due to a difference in the flowability of the insulating material, resulting in an irregular surface. If a plating process for forming wire patterns is performed in the state in which the insulating layer 350a has an irregular surface, a failure, such as deteriorated electrical characteristics, is generated because a plating thickness is partially different. Furthermore, the electric cutting of a wire is generated due to a region not partially plated. If a solder resist layer is coated on the region not partially plated, a difference between step coverages is further increased, resulting in a failure, such as a cracked chip. FIG. 8 also illustrates bonding pads 315, first face 313, semiconductor chip 310a, and a second face 317.

In order to solve the problems, in an embodiment of the present invention, the drift velocity of an insulating material in portions in which semiconductor chips are not disposed is controlled by disposing dummy patterns in an empty space between adjacent semiconductor chips. Accordingly, an insulating layer having a uniform surface can be formed.

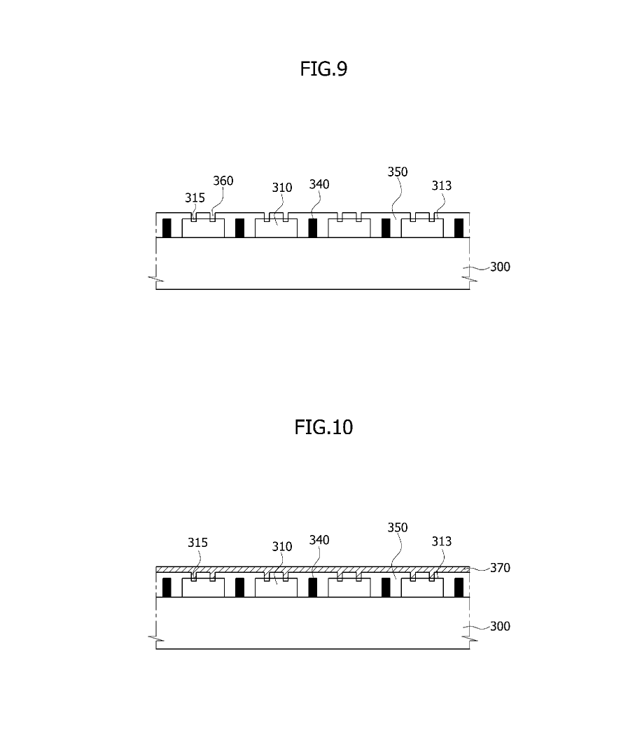

Referring to FIG. 9, via holes 360 through which the bonding pads 315 on the semiconductor chips 310 are exposed may be formed by etching the first insulating layer 350. FIG. 9 also illustrates dummy patterns 340, first face 313, and a substrate panel 300.

Referring to FIG. 10, a conductive layer 370 is formed on the bonding pads 315, including the via holes 360 (shown in FIG. 9), and the first insulating layer 350. The conductive layer 370 can be made of at least any one of copper (Cu), nickel (Ni), and gold (Au). The conductive layer 370 can be formed by an electroplating plating process. FIG. 10 also illustrates semiconductor chips 310, dummy patterns 340, first face 313, and substrate panel 300.

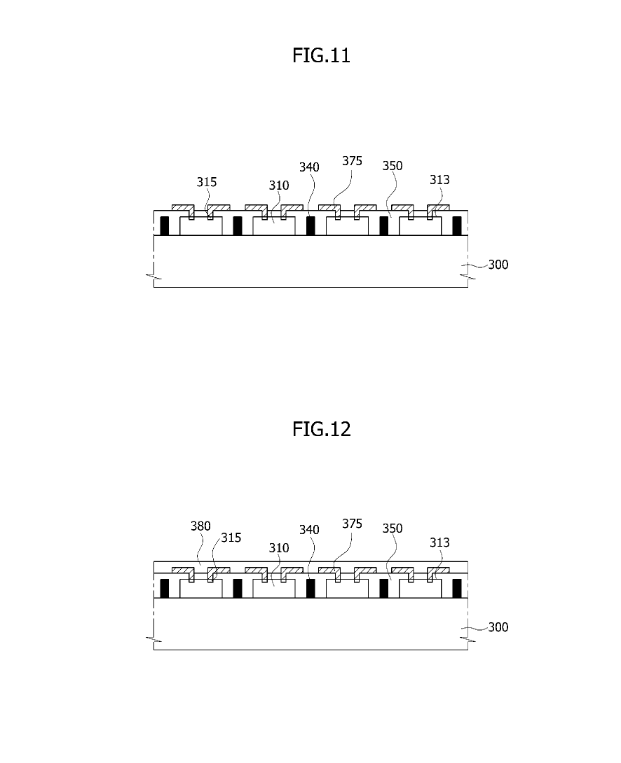

Referring to FIG. 11, the via holes 360 (shown if FIG. 9) are filled by patterning the conductive layer 370 (shown in FIG. 10), thereby forming wire patterns 375 electrically connected to the respective bonding pads 315. The wire patterns 375 can be formed by a photolithography process. The wire patterns 375 are configured to fill the via holes 360 and are extended up to a surface of the first insulating layer 350. In an embodiment of the present invention, since the wire patterns 375 may be formed on the first insulating layer 350 having a uniform surface, a portion in which the wire pattern 375 is not formed or a portion having an irregular thickness is not present. Accordingly, the occurrence of a failure, such as deteriorated electrical characteristics due to a portion having a partially different plating thickness, can be prevented. Also, FIG. 11 illustrates semiconductor chips 310, dummy patterns 340, a first face 313, and substrate panel 300.

Referring to FIG. 12, a second insulating layer 380 is formed on the wire patterns 375 and the first insulating layer 350. Also, FIG. 12 illustrates bonding pads 315, semiconductor chip 310, dummy pattern 340, first face 313, and substrate panel 300.

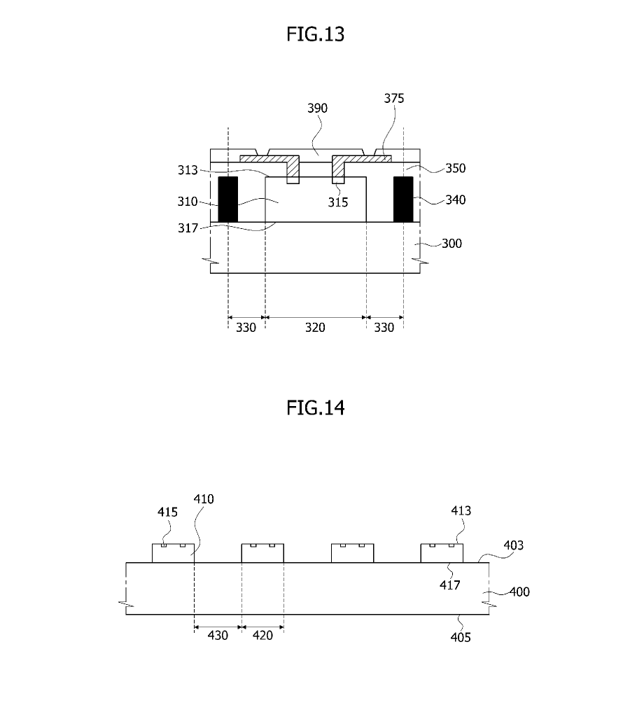

Referring to FIG. 13, second insulating layer patterns 390 through which surfaces of the wire patterns 375 are partially exposed may be formed by patterning the second insulating layer 380. The second insulating layer patterns 390 can be formed by a photolithography process. Next, the semiconductor chips 310 disposed over the substrate panel 300 can be grouped into a plurality of semiconductor packages by cutting portions indicated by dotted lines in FIG. 13 on the basis of the dummy patterns 340 disposed in the peripheral regions 330 surrounding the peripheries of the semiconductor chips 310. FIG. 13 also illustrates bonding pads 315, second surface 317, main region 320, first face 313, first insulating layer 350, and external connection terminal 395.

The semiconductor package in accordance with an embodiment of the present invention can be implemented to have a uniform surface by disposing the dummy patterns in the space between adjacent semiconductor chips and controlling the flowability of the insulating layer that fills the semiconductor chips.

In various embodiments, if a conductive material is used as a material forming the dummy patterns, the dummy patterns can function as through electrodes for coupling an upper layer and a lower layer together.

FIGS. 14 to 22 are diagrams illustrating a method of manufacturing a semiconductor package in accordance with an embodiment of the present invention. Like reference designators in FIGS. 14 to 22 denote like or corresponding elements, and thus their description may be omitted to avoid duplicate explanation.

Referring to FIG. 14, a plurality of semiconductor chips 410 may be disposed over a substrate panel 400. Each of the semiconductor chips 410 may include a first face 413 configured to have bonding pads 415 formed therein and a second face 417 configured to face the first face 413. The bonding pads 415 can be disposed along the central part of the semiconductor chip 410, but not limited thereto. The bonding pads 415 may include copper (Cu). The semiconductor chips 410 disposed over the substrate panel 400 can be adhered to the second face 417 of the substrate panel 400 through the medium of an adhesion layer (not shown). The semiconductor chips 410 may be disposed in the respective main regions 420 of the substrate panel 400. A peripheral region 430 through which a surface of the substrate panel 400 is exposed may be disposed between adjacent semiconductor chips 410. FIG. 14 also illustrates a second face 405 that faces the other face 403 of the substrate panel 400.

Referring to FIG. 15, one or more dummy patterns 440 may be disposed in the peripheral regions 430 of the substrate panel 400. The dummy patterns 440 may be disposed at specific intervals in the peripheries of the semiconductor chips 410. More particularly, the dummy patterns 440 may be disposed in the peripheral regions 430 that surround the main region 420 in which the semiconductor chip 410 may be disposed. Here, the dummy patterns 440 may be configured to include one or more pillars and consecutively disposed along the outer edges of the semiconductor chips 410. In this case, the dummy patterns 440 may have the same height or substantially the same height as the semiconductor chips 410. Furthermore, the dummy patterns 440 are made of a conductive material and can be made of at least any one of copper (Cu), nickel (Ni), and gold (Au), for example. Here, the dummy patterns 440 may include a first dummy pattern 440a and a second dummy pattern 440b formed on both sides between adjacent semiconductor chips 410.

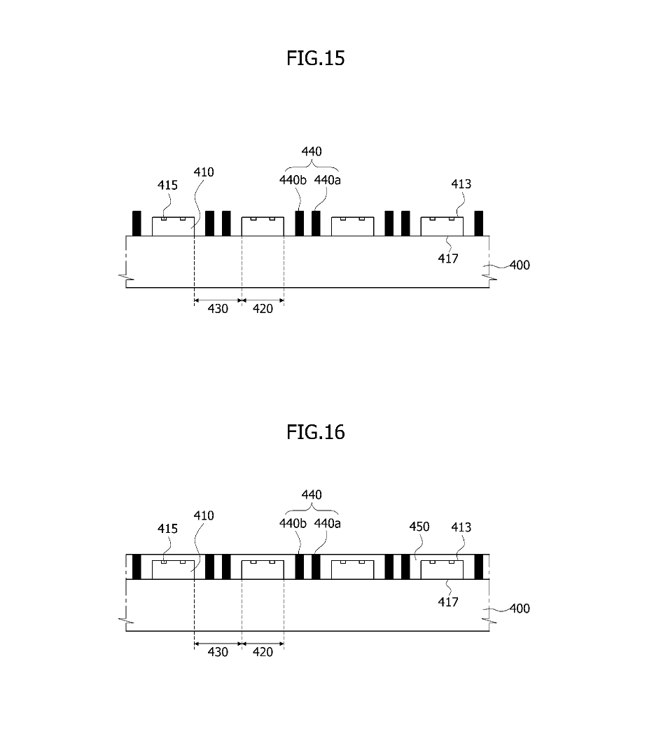

Referring to FIG. 16, structures disposed over the substrate panel 400, for example, the semiconductor chips 410 and the dummy patterns 440 are filled with an insulating layer 450. The insulating layer 450 can be formed by a vacuum lamination method. The semiconductor chips 410 and the space between adjacent semiconductor chips 410 are filled with an insulating material having flowability. The insulating material is coated to a thickness enough to cover the entire surface of the semiconductor chips 410. In this case, the insulating material has a uniform thickness in the entire substrate panel 400 because the drift velocity of the insulating material is controlled by the dummy patterns 440 disposed in the space between the semiconductor chips 410.

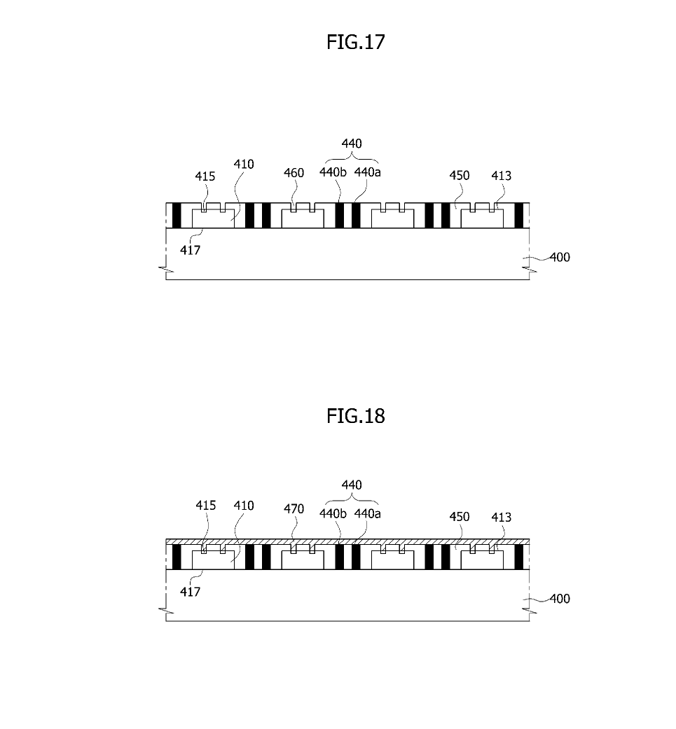

Referring to FIG. 17, via holes 460 through which the bonding pads 415 on the semiconductor chips 410 are exposed may be formed by etching the insulating layer 450.

Referring to FIG. 18, a first conductive layer 470 is formed on the bonding pads 415, including the via holes 460, and the insulating layer 450. The first conductive layer 470 can be made of at least any one of copper (Cu), nickel (Ni), and gold (Au). The first conductive layer 470 can be formed by an electroplating process.

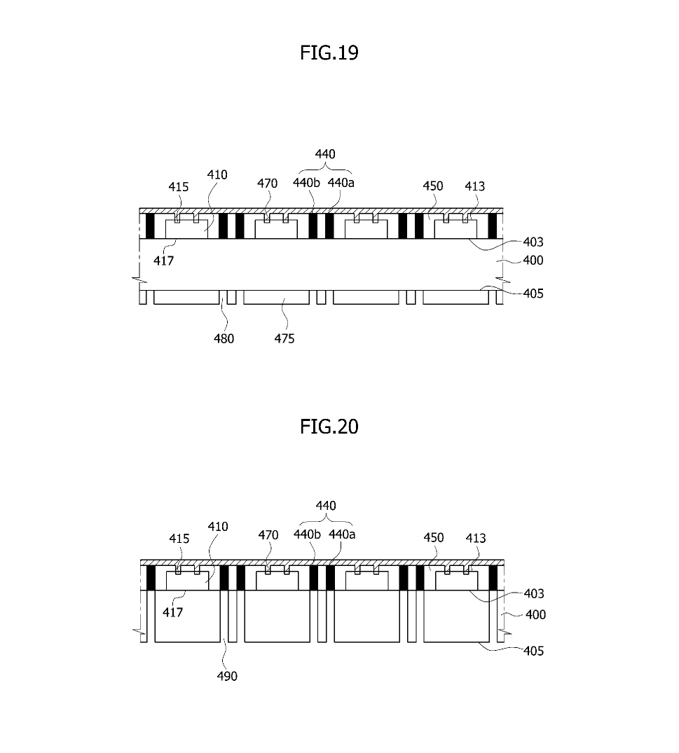

Referring to FIG. 19, hard mask film patterns 475 may be formed on a second face 405 that faces the other face 403 of the substrate panel 400 to which the semiconductor chips 410 are adhered. The hard mask film patterns 475 include open regions 480 through which a surface of the second face 405 of the substrate panel 400 is partially exposed.

Referring to FIG. 20, through holes 490 configured to penetrate the substrate panel 400 may be formed by etching the exposed portions of the second face 405 of the substrate panel 400 by using the hard mask film patterns 475 as a mask. The bottom surfaces of the dummy patterns 440 are exposed through the through holes 490.

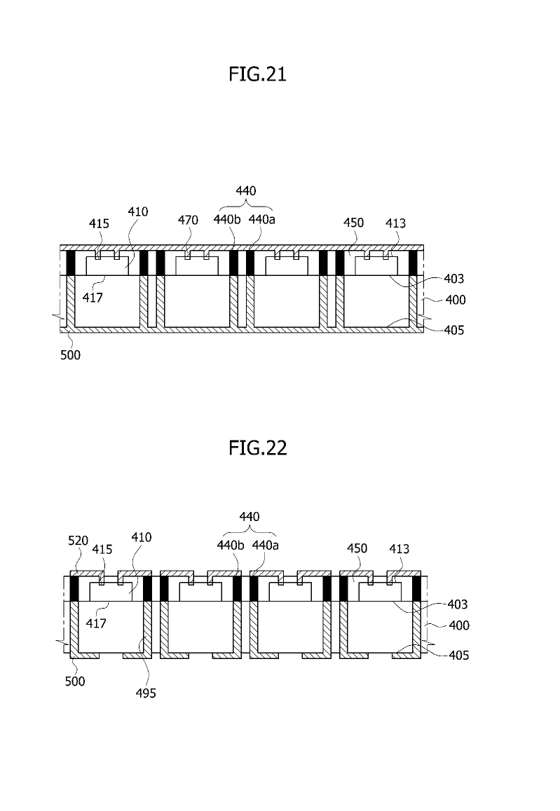

Referring to FIG. 21, a second conductive layer 500 is formed in the second face 405 of the substrate panel 400. The second conductive layer 500 is formed to a thickness that fills all the through holes 490 and covers a surface of the second face 405 of the substrate panel 400. The second conductive layer 500 can be made of at least one of copper (Cu), nickel (Ni), and gold (Au). The second conductive layer 500 can be formed by an electroplating process. The second conductive layer 500 is electrically connected to the first conductive layer 470 through the dummy patterns 440 made of a conductive material.

Referring to FIG. 22, through electrodes 495 each for coupling the first wire pattern 520, the dummy pattern 440, and the second wire pattern 500 and may be formed by patterning the first conductive layer 470 and the second conductive layer 500.

Next, the semiconductor chips 410 disposed over the substrate panel 400 can be grouped into a plurality of semiconductor packages by cutting portions indicated by dotted lines in FIG. 22 on the basis of the dummy patterns 440 disposed in the peripheral regions 430 surrounding the peripheries of the semiconductor chips 410.

The semiconductor package in accordance with an embodiment of the present invention can be implemented to have a uniform thickness by disposing the dummy patterns in the peripheral regions in which semiconductor chips are not disposed and controlling the flowability of the insulating material and can also be implemented to function as the through electrode for coupling an upper layer and a lower layer by using a conductive material as a material for the dummy patterns. Accordingly, a package production yield can be improved because processes for forming additional via holes and performing a plating process in order to couple the upper layer and the lower layer together are omitted.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A substrate for a semiconductor package, comprising:
a substrate panel;
semiconductor chips adhered over the substrate panel;
at least one dummy pattern disposed at intervals in peripheries of the semiconductor chips; and
an insulating layer formed over the substrate panel including the semiconductor chips and the dummy pattern.

2. The substrate of claim 1, wherein the dummy pattern has substantially the same height as the semiconductor chip.

3. The substrate of claim 1, wherein the insulating layer substantially has a uniform thickness.

4. The substrate of claim 1, wherein the dummy pattern is consecutively jointed together in a line form along outer edges of the semiconductor chips.

5. The substrate of claim 1, wherein the dummy pattern comprises patterns configured to have one or more pillars and consecutively disposed along outer edges of the semiconductor chips.

6. The substrate of claim 1, wherein the dummy patterns are made of an insulating material comprising solder resist or epoxy resins.

7. The substrate of claim 1, wherein the insulating layer comprises thermosetting resins or thermoplastic resins.

8. A semiconductor package, comprising:
a substrate;
semiconductor chips adhered over the substrate and configured to comprise bonding pads;
one or more dummy patterns disposed at specific intervals in peripheries of the semiconductor chips;
an insulating layer formed over the substrate comprising the semiconductor chips and the dummy patterns so that the bonding pads are exposed; and
wire patterns formed over the insulating layer and coupled with the bonding pads.

9. The semiconductor package of claim 8, wherein the dummy patterns are consecutively jointed together in a line form along outer edges of the semiconductor chips.

10. The semiconductor package of claim 8, wherein the dummy patterns comprise patterns configured to have one or more pillars and consecutively disposed along outer edges of the semiconductor chips.

11. The semiconductor package of claim 8, wherein the dummy patterns are configured to have a height identical with the semiconductor chips.

12. The semiconductor package of claim 8, wherein the dummy patterns are made of an insulating material comprising solder resist or epoxy resins.

13. The semiconductor package of claim 8, wherein the insulating layer comprises thermosetting resins or thermoplastic resins.

14. A method of manufacturing a semiconductor package comprising:
forming semiconductor chips over a substrate;
disposing a dummy pattern in peripheries of the semiconductor chips over the substrate;
forming an insulating material over the substrate including the semiconductor chips and the dummy pattern; and
using the dummy pattern to control a drift velocity of the insulating material.

15. The method of claim 14, wherein the insulating material comprises an insulating layer having a uniform thickness.

16. The method of claim 14, wherein the dummy pattern has substantially the same height as the semiconductor chip.

17. The method of claim 14, wherein the dummy patterns are consecutively jointed together in a line form along outer edges of the semiconductor chips.

18. The method of claim 14, wherein the dummy patterns comprise patterns having one or more pillars consecutively disposed along outer edges of the semiconductor chips.

19. The method of claim 14, wherein the dummy patterns are made of an insulating material comprising solder resist or epoxy resins.

20. The method of claim 14, wherein the insulating material comprise thermosetting resins or thermoplastic resins.
